(19) United States
(12) Patent Application Publication
(10) Pub. No.: US 2017/0227608 A1
(43) Pub. Date: Aug. 10, 2017

(54) COMMUNICATION TERMINAL DEVICE, REMAINING BATTERY AMOUNT CALCULATION METHOD, AND RECORDING MEDIUM STORING REMAINING BATTERY AMOUNT CALCULATION PROGRAM

(71) Applicant: FUJITSU LIMITED, Kawasaki-shi (JP)

(72) Inventor: Yukio TAKAHASHI, Machida (JP)

(73) Assignee: FUJITSU LIMITED, Kawasaki-shi (JP)

(21) Appl. No.: 15/498,456

(22) Filed: Apr. 26, 2017

Related U.S. Application Data
(62) Division of application No. 14/049,362, filed on Oct. 9, 2013.

(30) Foreign Application Priority Data
Mar. 18, 2013 (JP) 2013-055174

(51) Int. Cl. G01R 31/36

(52) U.S. Cl. CPC G01R 31/3648; G01R 31/3689

(57) ABSTRACT

A communication terminal device includes: a wireless unit configured to transmit and receive a radio wave; an operating circuit configured to be used for operating the communication terminal device; a battery configured to supply electric power to the communication terminal device; a power supply circuit configured to control supply of electric power from the battery; and an arithmetic processing unit configured to detect an operation on the operating circuit and a duration time of the operation, detect an external environment of the communication terminal device through the wireless unit, and calculate a first remaining battery amount of the battery based on the operation, the duration time, and the external environment.

### CROSS-REFERENCE TO RELATED APPLICATION

This application is a divisional of U.S. patent application Ser. No. 14/049,362, filed Oct. 9, 2013 which claims priority to Japanese patent application no. 2013-055174, filed on Mar. 18, 2013. The foregoing applications are incorporated herein by reference.

### FIELD

Embodiments discussed herein are related to a communication terminal device, a remaining battery amount calculation method, and a recording medium storing a remaining battery amount calculation program.

### BACKGROUND

In a communication terminal device, a rechargeable battery is used.

A related technique is disclosed in Japanese Laid-open Patent Publication No. 11-85337, Japanese Laid-open Patent Publication No. 2009-17621, or Japanese Laid-open Patent Publication No. 2004-157842.

### SUMMARY

According to one aspect of the embodiments, a communication terminal device includes: a wireless unit configured to transmit and receive a radio wave; an operating circuit configured to be used for operating the communication terminal device; a battery configured to supply electric power to the communication terminal device; a power supply circuit configured to control supply of electric power from the battery; and an arithmetic processing unit configured to detect an operation on the operating circuit and a duration time of the operation, detect an external environment of the communication terminal device through the wireless unit, and calculate a first remaining battery amount of the battery based on the operation, the duration time, and the external environment.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 illustrates an example of a mobile terminal device;

FIG. 2A and FIG. 2B illustrate an example of a log;

FIG. 3 illustrates an example of a basic consumption amount of electric power;

FIG. 4 illustrates an example of a moving state table;

FIG. 5 illustrates an example of a radio wave state table;

FIG. 6 illustrates an example of a temperature addition value;

FIG. 7 illustrates an example of a battery consumption amount curve;

FIG. 8 illustrates an example of battery consumption amount data;

FIG. 9 illustrates an example of display of battery consumption;

FIG. 10 illustrates an example of an operation of a mobile terminal device;

FIG. 11 illustrates an example of battery-life state check;

FIG. 12 illustrates an example of a communication system; and

FIG. 13 illustrates an example of a computer.

### DESCRIPTION OF EMBODIMENTS

For example, a portable information terminal includes a main control unit, and a sub-controller that is capable of operating with less electric power than the main controller and controls a voltage detection circuit and a power supply circuit. In the portable information terminal, the sub-controller controls the voltage detection circuit detecting the voltage of a battery, and the power supply circuit supplying electric power to the main controller and a communication controller. Owing to such control, the run time of the portable information terminal may become longer.

For example, in response to a situation, the communication terminal device outputs different kinds of guidance relating to charging. The communication terminal device includes a charging log, a usage log, a power consumption prediction mechanism, and a charging determination mechanism. The charging log is information where the charging start time of a battery and the location information of the charging thereof are recorded with being associated with each other. The usage log is information where the temporal usage situation of the communication terminal device is recorded. From the charging log and the usage log, the power consumption prediction mechanism predicts power consumption to be used before a subsequent charging prediction time. When a remaining battery amount is less than the predicted power consumption, the charging determination mechanism prompts charging in response to the location of the communication terminal device or output a usage time until a scheduled charging time.

In an eco-driving diagnostic system in a vehicle, based on the consumption amount of fuel or a driving situation, which are transmitted to a center, the consumption amount of fuel or the amount of emission of greenhouse effect gas or the like due thereto is calculated. So as to enlighten on performing eco-driving based on the calculated information, contents may be provided to a portable terminal.

The available time of a battery, which is described as a catalog value in the communication terminal device, is described in regard to a standby time in many cases. Therefore, depending on the usage state or the like of a user, there may be a large difference between the available times.

Depending on an operation situation, even though the communication terminal device has been only used for a significantly short time period with respect to the catalog value, charging may be needed in some cases. In such a case, the user may feel that a battery life is not good, and may recognize that there is a problem on a communication terminal device side.

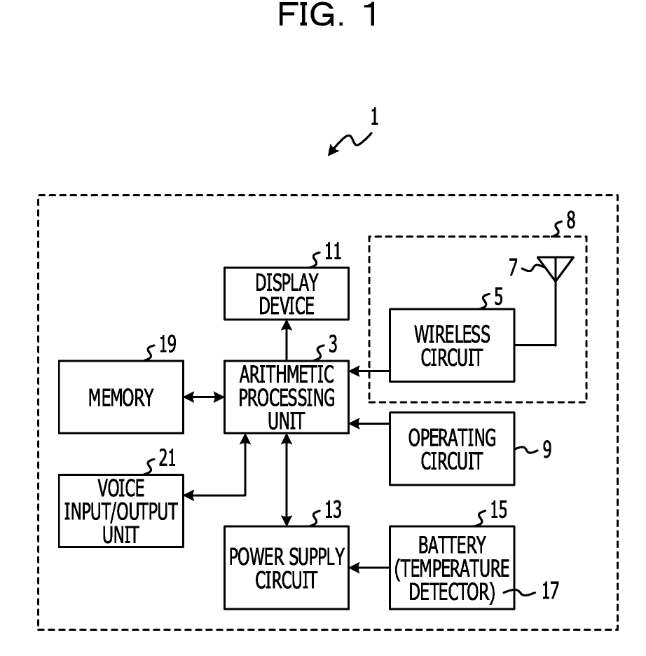

FIG. 1 illustrates an example of a mobile terminal device. A mobile terminal device 1 includes an arithmetic processing unit 3, a wireless circuit 5, an antenna 7, an operating circuit 9, a display device 11, a power supply circuit 13, a battery 15, a temperature detector 17, a memory 19, and a voice input/output unit 21. The mobile terminal device 1 may be a communication terminal device such as a mobile phone device.

The arithmetic processing unit 3 may be an arithmetic processing device performing processing relating to the operation of the mobile terminal device 1. The wireless circuit 5 generates a transmission signal used for transmitting a voice and other information, and extracts a signal from a radio wave the antenna 7 has received. The antenna 7 may be a transmission/reception device that transmits and receiving radio waves. Owing to a wireless unit 8 including the wireless circuit 5 and the antenna 7, the mobile terminal device 1 performs wireless communication. The operating circuit 9 may be a circuit that detects an instruction, which is issued to the mobile terminal device 1, and converting the instruction into a signal. The display device 11 may be a device that performs display and, for example, a liquid crystal display device or the like.

The power supply circuit 13 may be a circuit that controls the battery 15. The battery 15 is a battery that supplies electric power to the mobile terminal device 1, and may be a rechargeable battery such as a lithium-ion battery. The temperature detector 17 may be a temperature detection device that detects the temperature of the battery 15. The memory 19 is a storage device including, for example, a read only memory (ROM), a random access memory (RAM), or the like, and stores therein a program for controlling the operation of the mobile terminal device 1, and data in response to processing. For example, information used for calculating a remaining battery amount may be stored in advance. The voice input/output unit 21 includes, for example, a microphone, a speaker, and so forth, and may be a device that converts an electrical signal into a voice, outputs the voice, and converts a detected voice into an electrical signal.

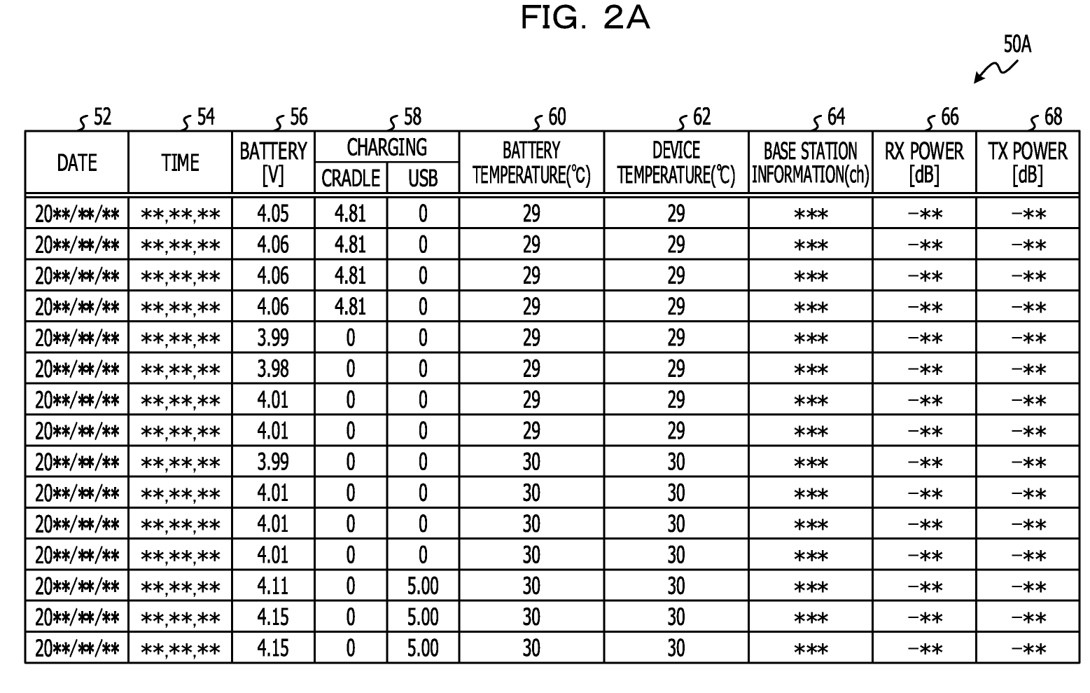

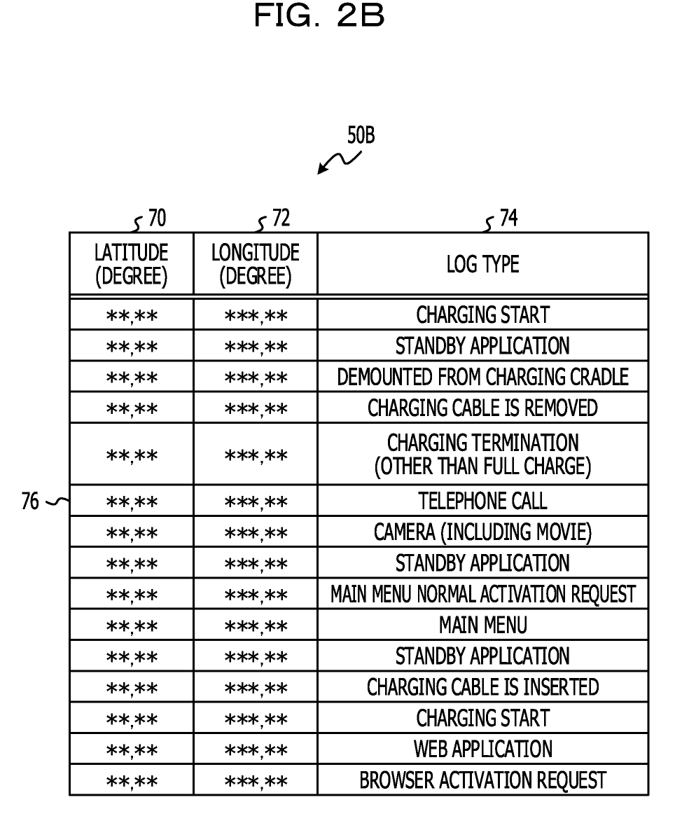

FIG. 2A and FIG. 2B illustrate an example of a log. FIG. 2A illustrates a log 50A, and FIG. 2B illustrates a log 50B. The log 50A and the log 50B are included in a log 50, and may be collectively referred to as the log 50. In the arithmetic processing unit 3, for example, at given time intervals or every time a start or a termination of an operation of the operating circuit 9 has been detected, various kinds of data are detected and stored in the log 50. The log 50 is stored in, for example, the memory 19. The log 50 includes a date 52, a time 54, a battery voltage 56, a charging voltage 58, a battery temperature 60, a device temperature 62, base station information 64, reception power 66, transmission power 68, a latitude 70, a longitude 72, a log type 74, or the like.

The date 52 is a date when the log 50 has been acquired. The time 54 is a time when the log 50 has been acquired. The battery voltage 56 is the voltage of the battery 15 when the log 50 has been acquired, and the battery voltage 56 is detected by the arithmetic processing unit 3 through the power supply circuit 13. The charging voltage 58 is a charging voltage applied to the battery 15 through, for example, a cradle or a Universal Serial Bus (USB). The battery temperature 60 is the temperature of the battery 15, detected by the temperature detector 17. The reception power 66 is the electric power of a radio wave received from the antenna 7 through the wireless circuit 5. The transmission power 68 is the electric power of a radio wave output from the antenna 7 through the wireless circuit 5.

The latitude 70 is the latitude of a base station serving as a target to and from which the mobile terminal device 1 transmits and receives. The longitude 72 is the longitude of the base station serving as a target to and from which the mobile terminal device 1 transmits and receives. The log type 74 is the type of an operation detected by the operating circuit 9.

In FIG. 2B, while the log types 74 are different in the individual logs 50, there may also be various patterns including a case where the same log type 74 is recorded continuously more than once, for example, when the log 50 is acquired at the given time intervals.

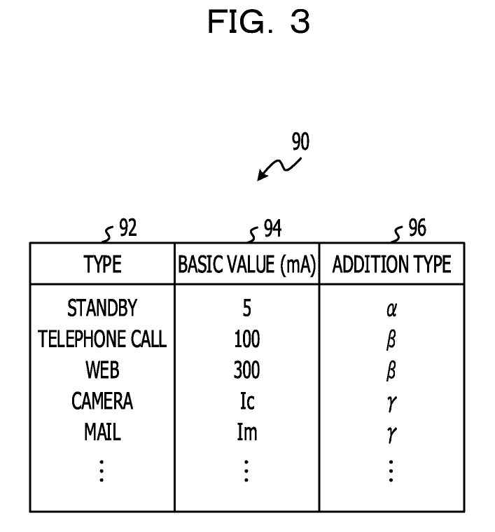

FIG. 3 illustrates an example of a basic consumption amount of electric power. In FIG. 3, the basic consumption amount of the electric power of the mobile terminal device 1 illustrated in FIG. 1 is illustrated. A basic consumption amount 90 may be a table to be referred to when a battery consumption amount is calculated in response to the type of an operation. The basic consumption amount 90 includes a type 92, a basic value 94, and an addition type 96. The type 92 is the type of an operation performed in the mobile terminal device 1, and, for example, “standby”, “telephone call”, “WEB”, “camera”, “mail”, or the like. The “standby” indicates a state where another operation is not performed when the mobile terminal device 1 has been turned on. The “telephone call” indicates a state where a telephone call is performed owing to the telephone function of the mobile terminal device 1. The “WEB” indicates a state where information is transmitted and received through the wireless circuit 5 and the antenna 7. The “camera” indicates a state where an image-capturing function is used. The “mail” indicates a state where the read/write or the like of an electronic mail is performed.

The basic value 94 indicates a current value consumed typically in the case of the state of the type 92. The addition type 96 indicates a standard by which a consumption current is added owing to a condition other than the type 92, the condition including, for example, a radio wave intensity, a device temperature, or the like. For example, a case where the addition type 96 is “α” may indicate a type where a current value is added depending on whether or not the mobile terminal device 1 is moving. A case where the addition type 96 is “β” may indicate a type where a current value is added in response to, for example, the radio wave intensity and the battery temperature. A case where the addition type 96 is “γ” may indicate a type where addition due to another factor is not performed. When an external environment such as the radio wave intensity or the device temperature, which relates to the type 92, is considered to be deteriorated, the battery consumption amount may be calculated owing to the addition type 96 so that battery consumption becomes large.

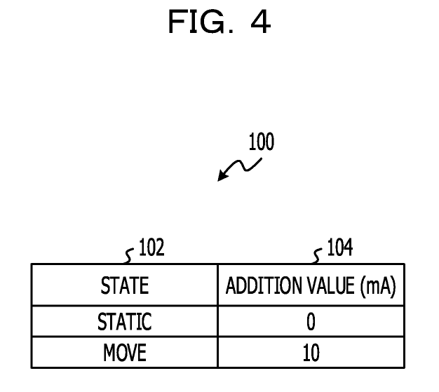

FIG. 4 illustrates an example of a moving state table. A moving state table 100 is a table indicating a current value to be added to the basic value depending on a state where the mobile terminal device 1 is moving or remains static. The moving state table 100 includes a state 102 and an addition value 104. The state 102 indicates “static” and “move”. For example, the addition value 104 is “0” at the time of the “static”, and indicates that “10” (mA) is to be added at the time of the “move”. Whether in the “static” or the “move” may be judged depending on, for example, whether or not the base station information 64 of the log 50 is changing.

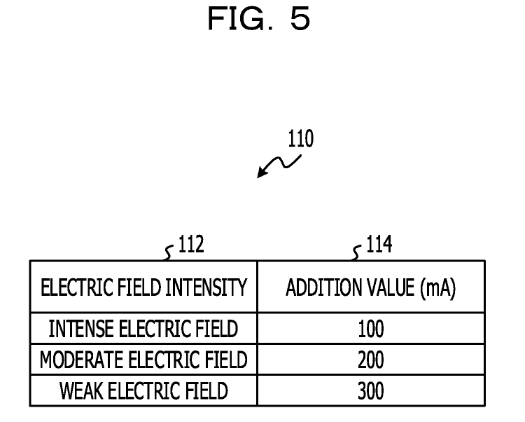

FIG. 5 illustrates an example of a radio wave state table. A radio wave state table 110 is a table indicating a current value to be added in response to the electric field intensity of the reception radio wave of the mobile terminal device 1. The radio wave state table 110 includes an electric field intensity 112 and an addition value 114. The electric field intensity 112 indicates an “intense electric field”, a “moderate electric field”, or a “weak electric field”. The addition value 114 may be, for example, “100 mA” in the case of the “intense electric field”, the addition value 114 may be, for example, “200 mA” in the case of the “moderate electric field”, and the addition value 114 may be, for example, “300 mA” in the case of the “weak electric field. The electric field intensity 112 may be judged owing to, for example, the reception power 66 in the log 50.

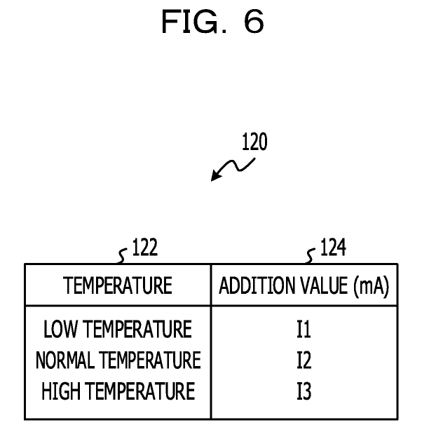

FIG. 6 illustrates an example of a temperature addition value. A temperature addition value 120 is a table indicating a current value to be added in response to, for example, the temperature of the battery 15 which is measured by the temperature detector 17. The temperature addition value 120 includes a temperature 122 and an addition value 124. For example, I2 (mA) is added as the addition value 124 when the temperature 122 is a “low temperature”, I2 (mA) is added as the addition value 124 in the case of a “normal temperature”, and I3 (mA) is added as the addition value 124 in the case of a “high temperature”. The battery temperature 60 or the device temperature 62 in the log 50 may be used for the temperature 122. As for the temperature 122, a corresponding temperature range may be set in advance, and the temperature 122 may also be classified based on the battery temperature 60 or the device temperature 62.

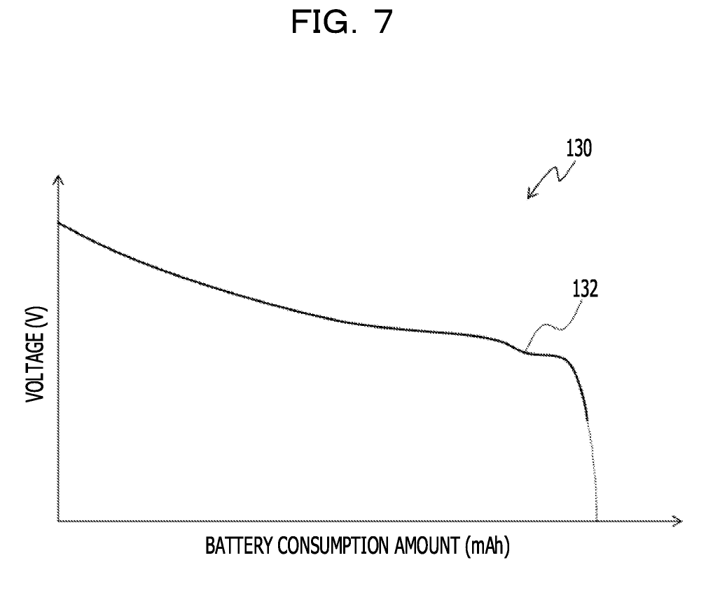

FIG. 7 illustrates an example of a battery consumption amount curve. As illustrated in FIG. 7, a battery consumption amount curve 130 is a curved line indicating the consumption amount of a battery at the time of a given battery voltage. In the battery consumption amount curve 130, a horizontal axis indicates the battery consumption amount, and a vertical axis indicates a battery voltage. For example, the battery 15 may also express the battery consumption amount curve 130 illustrated in FIG. 7.

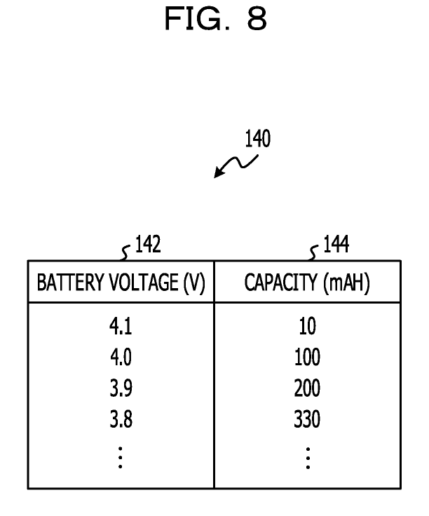

FIG. 8 illustrates an example of battery consumption amount data. Battery consumption amount data 140 is obtained by converting the battery consumption amount 132 illustrated in FIG. 7 into a table. The battery consumption amount data 140 includes a battery voltage 142 and a consumption amount 144. For example, when the battery voltage 142=4.1 (v), the consumption amount 144=10 (mAh) may be recorded. The arithmetic processing unit 3 detects the voltage of the battery 15, and calculates a battery capacity at the time of the termination of charging, based on the battery consumption amount data 140 and a battery capacity at the time of full charge. A calculated battery consumption amount and the battery consumption amount of the battery consumption amount data 140 may be compared with each other, and adjustment may be performed.

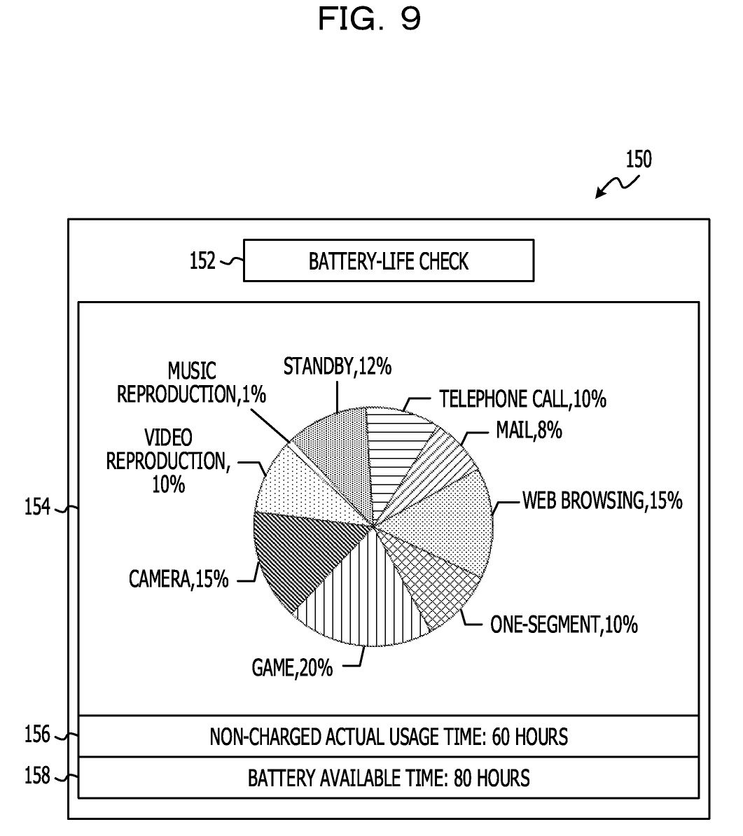

FIG. 9 illustrates an example of display of battery consumption. In FIG. 9, based on a battery consumption amount calculated in response to the log 50 and the moving state table 100, the radio wave state table 110, the temperature addition value 120, the battery consumption amount data 140, or the like, display is performed. A display example 150 may be displayed, for example, while charging is performed.

The display 150 includes a title 152, a circular graph 154, a usage-time display unit 156, and an available time display unit 158. The title 152 indicates the content of the display 150. The circular graph 154 indicates the percentage of a battery consumption amount with respect to each operation type from the latest charging termination up to a current time or up to the start of the latest charging. The circular graph 154 indicates that a consumption amount due to a game is the largest and a consumption amount due to WEB browsing is the second largest.

The usage-time display unit 156 indicates a usage time up to the current moment after the latest charging termination or up to the start of current charging in the case of being charged. The available time display unit 158 indicates the prediction value of the available time, which is calculated in accordance with the utilization form of the user illustrated in the circular graph 154, of the mobile terminal device 1, which is charged most recently. A battery capacity immediately after the charging termination of the charging having finished most recently may be obtained based on, for example, the battery consumption amount data 140 illustrated in FIG. 8. The display 150 indicates that the use of about 80 hours from the latest charging termination has been predicted to be available, for example.

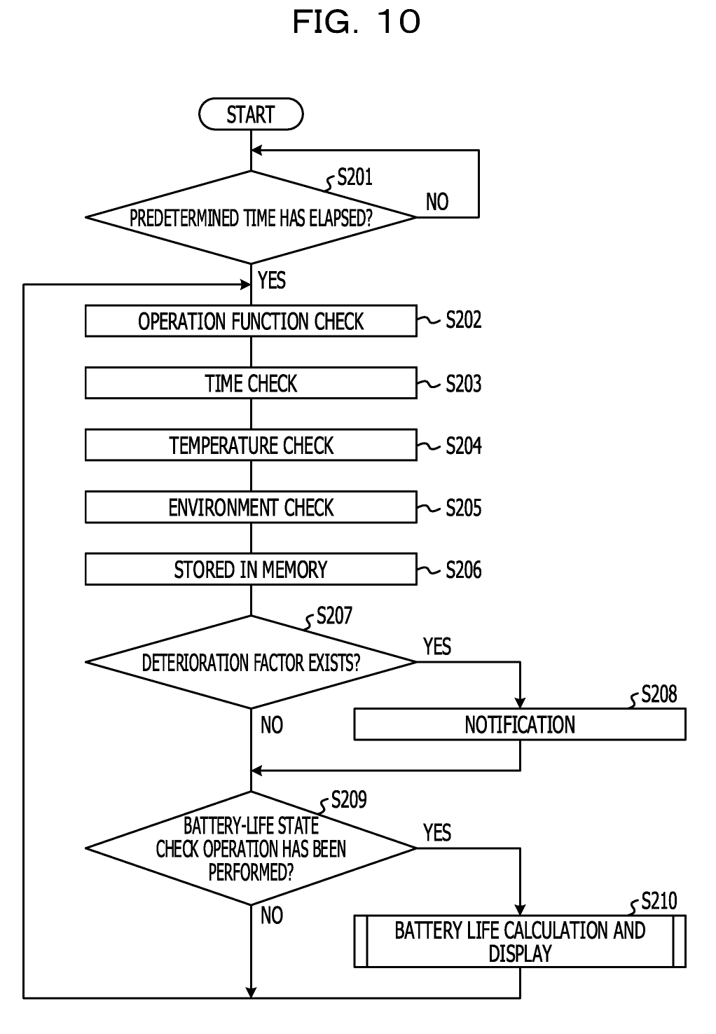

FIG. 10 illustrates an example of an operation of a mobile terminal device. The mobile terminal device 1 illustrated in FIG. 10 acquires the log 50 at the given time intervals. For example, the arithmetic processing unit 3 repeats judgment until a given time has elapsed (S201: NO), and when it has been judged that the given time has elapsed (S201: YES), the arithmetic processing unit 3 checks the arithmetic processing unit 3′s own operation function (S202). For example, when an operation has been acquired through the operating circuit 9, the arithmetic processing unit 3 recognizes the operation. For example, as illustrated in the log type 74 in FIG. 2B, the arithmetic processing unit 3 acquires “charging start”.

The arithmetic processing unit 3 performs time check (S203). For example, by a function provided in the arithmetic processing unit 3, a date and a time may be acquired like the date 52 and the time 54. The arithmetic processing unit 3 checks a temperature (S204). The arithmetic processing unit 3 acquires a temperature such as the battery temperature 60, for example, from the temperature detector 17 through the power supply circuit 13. The temperature detector 17 may also acquire the temperature of the battery 15, and may also acquire the temperature of a device, such as the device temperature 62, from a temperature detector which acquires the temperature of a device.

The arithmetic processing unit 3 performs environment check (S205). For example, the arithmetic processing unit 3 measures the battery voltage 56 of the battery 15 through the power supply circuit 13. Through the antenna 7 and the wireless circuit 5, the base station information 64, the reception power 66, the transmission power 68, the latitude 70, the longitude 72, or the like is acquired. The arithmetic processing unit 3 stores, in the memory 19, measurement values acquired in the S202 to the S205, as the log 50.

The arithmetic processing unit 3 judges whether or not a deterioration factor exists in the acquired log 50, the deterioration factor shortening, for example, a battery available time (S207). The deterioration factor includes, for example, a case where the reception power 66 is electric power less than or equal to a given value, a case where a temperature is less than or equal to a given value, a case where a temperature is greater than or equal to a given value, or a case where move is continued.

When it has been judged that the deterioration factor exists (S207: YES), the arithmetic processing unit 3 causes, for example, the display device 11 or the like to display the existence of a factor deteriorating a battery life, and notifies the user of the existence (S208). When no deterioration factor exists (S207: NO), the processing proceeds to S209.

The arithmetic processing unit 3 judges whether or not a battery-life state check operation has been performed through the operating circuit 9 (S209). The battery-life state check operation may be an operation for causing a remaining battery amount and so forth to be calculated or an operation for causing processing for displaying, for example, the display example 150 to be executed. When it has been judged that the battery-life state check operation has been performed (S209: YES), the processing proceeds to S210, and the calculation of a battery life and display (ECO check) are performed (S210). When no battery-life state check operation has been confirmed (S209: NO), the processing returns to the S202 and is repeated.

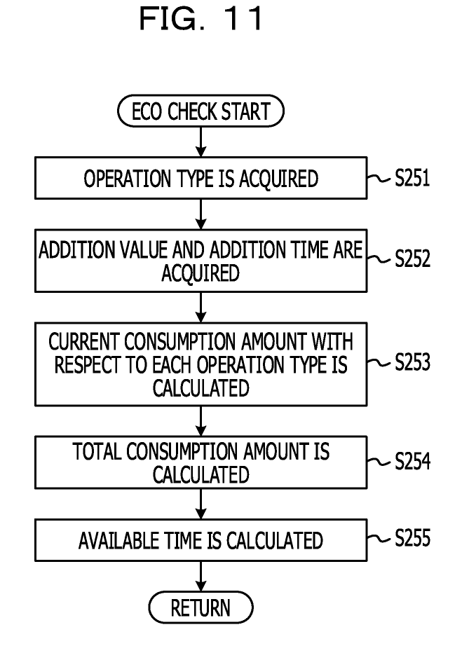

FIG. 11 illustrates an example of battery-life state check. As illustrated in FIG. 11, when an operation used for battery-life state check has been detected in the S209, the arithmetic processing unit 3 defines, as the reference target time period of a battery consumption amount, a time period from the latest “charging termination” to a time point when the operation in the S209 has been performed, for example, like data 76 in the log 50. From the log 50 in the reference target time period, the arithmetic processing unit 3 acquires the log type 74 of an operation and the duration time of the operation in the log type 74 (S251). From the log 50, the arithmetic processing unit 3 acquires the addition value and the addition time of a current consumption amount corresponding to the acquired log type 74 (S252). Based on the log type 74, the duration time, and the addition value and the addition time of a current consumption amount, the arithmetic processing unit 3 calculates a current consumption amount with respect to each operation type (S253).

For example, from the acquired log type 74, the arithmetic processing unit 3 acquires, as a duration time, a time having elapsed before a time when another log type 74 has been detected next. In response to the log type 74, the arithmetic processing unit 3 refers to the addition type 96, illustrated in FIG. 3, where the type 92 corresponding to the log type 74 is classified. For example, when the log type 74 is “standby application”, the “standby” corresponds in the type 92. At this time, since the addition type 96 is “α”, the arithmetic processing unit 3 refers to the base station information 64, for example, within a given time before or after the duration time of the “standby application” in the log type 74 in the log 50, and judges whether or not a coupled base station has changed. When the coupled base station has changed, it is judged that the mobile terminal device 1 is moving, and when the coupled base station has not changed, it is judged that the mobile terminal device 1 is not moving.

When having been judged to be moving, the arithmetic processing unit adds, to the basic value 94=“5 mA” of the “standby”, the addition value 104=“10 mA” at the time of the state 102=“move” in the moving state table 100 illustrated in FIG. 4, and hence, calculates a battery consumption amount per unit time in that state. The battery consumption amount is obtained by multiplying a time when a given state is continued by a consumption current at the given state. For example, when move in a standby state has been continued during a t1 time, the battery consumption amount=(5+10)×t1 (mAh) is calculated. When having been judged not to be moving, there is no addition value, and the battery consumption amount is calculated using the basic value 94.

For example, when the type 92 is the “telephone call” and the addition type 96 is the “β”, the arithmetic processing unit 3 refers to the reception power 66 and the battery temperature 60 at a time corresponding to the “telephone call” in the log 50. The arithmetic processing unit 3 refers to which of the electric field intensities 112 in the radio wave state table 110 illustrated in FIG. 5 the referred-to reception power 66 corresponds to, and adds the corresponding addition value 114 to the basic value 94. The arithmetic processing unit 3 refers to which of the temperatures 122 in the temperature addition value 120 illustrated in FIG. 6 the battery temperature 60 corresponds to, and adds the corresponding addition value 124. For example, when the reception power 66 is the “intense electric field” and a state where the battery temperature 60 corresponds to the “high temperature” has been continued during a t2 time, the battery consumption amount=(100+100+I3)×t2 (mAh) may be satisfied.

By calculating and adding the battery consumption amount with respect to each of all the operation types during that time period, in such a way as described above, the arithmetic processing unit 3 calculates the total consumption amount of the reference target time period (S254). In the same way as the reference target time period, the arithmetic processing unit 3 calculates the available time of the mobile terminal device 1 when the mobile terminal device 1 has been used (S255). For example, the battery voltage 56 in the log 50 in FIG. 2A and the battery consumption amount data 140 illustrated in the FIG. 8 are referred to, and a time to elapse before the battery consumption amount reaches a given value is calculated. The given value may be a value preliminarily set in accordance with a battery capacity, for example, as a battery consumption amount where charging becomes desirable. The processing may return to FIG. 10.

In the mobile terminal device 1 illustrated in FIG. 1, based on the log type 74 in the log 50, the battery consumption amount is calculated. Using the log type 74, a current consumption amount is changed based on an environment into which the mobile terminal device 1 is put, for example, a radio wave intensity, the temperature of the mobile terminal device 1 or the battery 15, or the presence or absence of move. When the external environment has been deteriorated, the battery consumption amount is calculated so that battery consumption becomes larger. Therefore, a remaining battery amount may be presented in response to an actual battery consumption amount.

A usage time or a battery consumption amount is displayed with respect to each log type 74, and hence, it may be possible for the user to recognize the user's actual usage of the mobile terminal device 1. Based on such presentation, the user may recognize what operation a battery is greatly consumed by.

When there is a difference between a continuous standby time or an available time, described in a catalog presented by a maker, and an actual available time, there may be reduced the occurrence of a misunderstanding that there is a problem in the performance of a battery. The user's dissatisfaction with the battery consumption amount may be reduced.

When the battery consumption amount is calculated, information such as a radio wave intensity or a temperature is incorporated. Therefore, a battery consumption amount whose accuracy is high may be calculated. When it is determined that a factor exists which causes the battery consumption amount to increase, the user is notified. Therefore, the desirability of charging may be correctly acknowledged. When the user feels that a battery life is not good, it may be determined, based on the result of battery-life state check, whether or not a failure has occurred in the mobile terminal device 1.

For example, when the sensitivity of the voice input/output unit 21 is changed based on an ambient noise, an addition value may be provided in a current value corresponding to the ambient noise. As an external environment, other information such as weather may be used. For example, in response to the percentage of clouds, the range of an electric field intensity may also be changed. Information may also be acquired from an external database through the wireless unit 8.

For example, the circular graph 154 may also be displayed by another display method. A battery consumption amount may not be displayed but a usage time may also be displayed. As for the usage-time display unit 156 or the available time display unit 158, another numerical value such as the proportion of a spent time to the available time may also be displayed. The presentation of the battery consumption amount may also be performed owing to a voice.

The sequence of the S202 to the S205, which corresponds to the processing where the arithmetic processing unit 3 acquires the log 50, is an example, and another sequence may also be adopted. The latitude 70 or the longitude 72 may also be the latitude or the longitude of a base station, and may also be acquired using the function of the Global Positioning System (GPS) of the mobile terminal device 1. In a method where the duration time of the influence of the external environment is determined based on the log 50, the timing of the log 50 or the form of the reference value may be arbitrary.

The display device 11 and the voice input/output unit 21 are examples of a presentation unit, and the memory 19 is an example of a storage unit. The storage unit may also be a detachable portable recording medium.

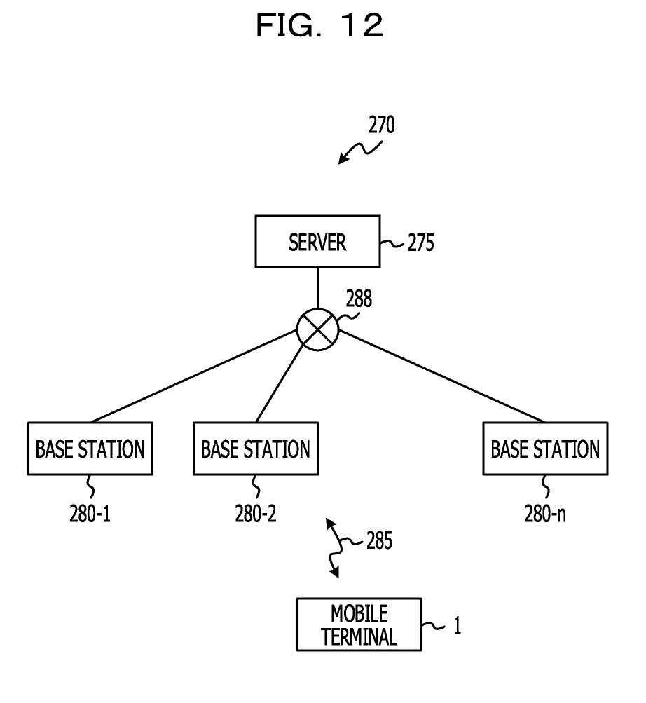

FIG. 12 illustrates an example of a communication system. In FIG. 12, the same number may be assigned to substantially the same element as or similar to the element illustrated in FIG. 1, and the description thereof may be omitted or reduced. A communication system 270 includes a server 275, a plurality of base stations 280-1, . . . , and 280-n (hereinafter, collectively referred to as base stations 280), and a mobile terminal device 1. The server 275 is coupled to the plural base stations 280 through a wired or wireless network 288. In response to the location of the mobile terminal device 1, the mobile terminal device 1 is coupled to one of the base stations 280 depending on wireless communication.

The mobile terminal device 1 illustrated in FIG. 12 may have substantially the same configuration as or similar to the mobile terminal device 1 illustrated in FIG. 1. The base station 280 may be a communication device that communicates with a plurality of communicatable mobile terminal devices 1, for example, at certain time intervals and performs given communication in response to a request from the mobile terminal device 1 or a request from another mobile terminal device 1 or the like. The server 275 may also be an information processing device that controls the communication of the base station 280, the mobile terminal device 1, and so forth and manages various kinds of information. The server 275 may also be, for example, a computer.

The server 275 acquires, from the mobile terminal device 1 through the wireless unit 8 and the base station 280, the log 50 stored in the memory 19 in the mobile terminal device 1, for example, in the S206 in FIG. 10, and stores the log 50 in a storage unit in the server 275. The basic consumption amount 90, the moving state table 100, the temperature addition value 120, the battery consumption amount data 140, and so forth may be preliminarily stored in the storage unit. When performing the battery-life state check, the mobile terminal device 1 requests the server 275 to check, through the wireless unit 8. For example, in substantially the same way as the method illustrated in FIG. 11, based on a request, the server 275 checks a battery life, and transmits a result to the mobile terminal device 1. In the mobile terminal device 1, the received result is presented. By such processing as described above, substantially the same advantageous effect as the above-mentioned remaining battery amount presentation method may be obtained.

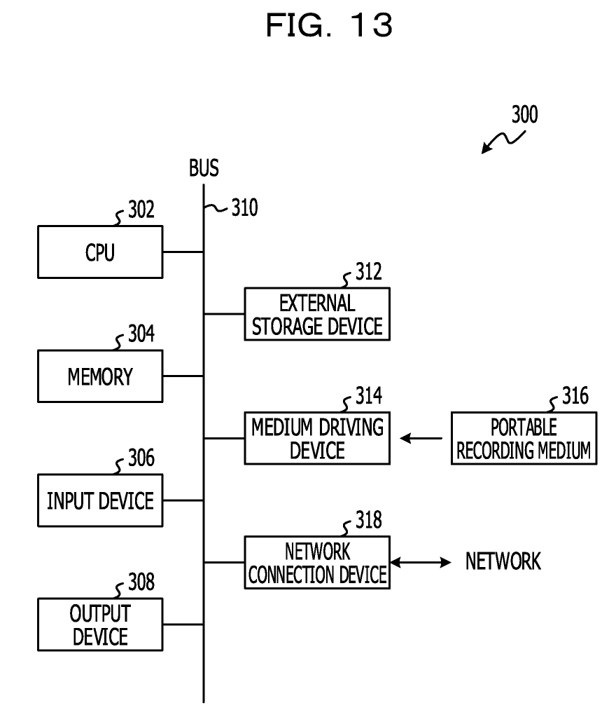

FIG. 13 illustrates an example of a computer. In FIG. 13, the hardware configuration of the computer is illustrated. A computer 300 may execute the operation of the above-mentioned remaining battery amount presentation method. In the computer 300 illustrated in FIG. 13, a central processing unit (CPU) 302, a memory 304, an input device 306, an output device 308, an external storage device 312, a medium driving device 314, a network connection device, and so forth are coupled through a bus 310.

The CPU 302 may be an arithmetic processing unit controlling the operation of the whole computer 300. The memory 304 may be a storage unit that stores therein a program for controlling the operation of the computer 300 and is used as a working area as appropriate when the program is executed. The memory 304 may be, for example, a random access memory (RAM), a read only memory (ROM), or the like. The input device 306 may be a device that acquires the input of various kinds of information from a user, based on an operation of the user of the computer, and sends the acquired input information to the CPU 302. The input device 306 may be, for example, a keyboard device, a mouse device, or the like. The output device 308 may be a device outputting a processing result of the computer 300, and a display device or the like is included. For example, the display device displays a text or an image in response to display data sent by the CPU 302.

The external storage device 312 may be, for example, a storage device such as a hard disk, and stores therein various kinds of control programs to be executed by the CPU 302, acquired data, or the like. A program for calculating a remaining battery amount, the basic consumption amount 90, the moving state table 100, the radio wave state table 110, the temperature addition value 120, or the battery consumption amount data 130 may also be stored. The medium driving device 314 may be a device for performing writing and reading on the portable recording medium 316. The CPU 302 reads out, through the recording medium driving device 314, a predetermined control program stored in the portable recording medium 316, executes the predetermined control program, and hence, performs various kinds of control processing. The portable recording medium 316 may be, for example, a Compact Disc (CD)-ROM, a Digital Versatile Disc (DVD), a Universal Serial Bus (USB) memory, or the like. The network connection device 318 may be an interface device managing the transmission and reception of various kinds of data with an external portion by wired or wireless. The bus 310 may be a communication path coupling the above-mentioned individual devices to one another and performing the exchange of data.

A program causing the computer to execute the remaining battery amount presentation method may be stored in, for example, the external storage device 312. The CPU 302 reads out the program from the external storage device 312, and causes the computer 300 to present a remaining battery amount. A control program may be created that is used for causing the CPU 302 to perform processing for presenting the remaining battery amount, and may be stored in the external storage device 312. For example, based on a predetermined instruction from the input device 306, the CPU 302 may read out and execute this control program from the external storage device 312. The program may also be stored in the portable recording medium 316.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A communication terminal device comprising:
a wireless unit configured to transmit and receive a radio wave;
an operating circuit configured to be used for operating the communication terminal device;
a battery configured to supply electric power to the communication terminal device;
a power supply circuit configured to control supply of electric power from the battery; and
an arithmetic processing unit configured to:
detect types of operations on the operating circuit and duration times of the operations,
detect an external environment of the communication terminal device through the wireless unit,
store the types of operations, the duration times of the operations and the external environment in a memory as a log,
judge whether a deterioration factor shortening a battery available time of the battery exists in the log,
make a notification of the deterioration factor when the deterioration factor exists in the log,
judge whether a check operation which is based on the notification of the deterioration factor and instructs to calculate a remaining battery amount of the battery is detected, and
calculate, when the check operation is detected, a first remaining battery amount of the battery based on the types of operations, the duration times of the operations and the external environment of the log.

2. The communication terminal device according to claim 1, wherein the arithmetic processing unit calculates the first remaining battery amount so that a second remaining battery amount of the battery, which is calculated in accordance with the types and the duration times, decreases in response to deterioration of the external environment.

3. The communication terminal device according to claim 1, further comprising:
a presentation unit configured to present the first remaining battery amount.

4. The communication terminal device according to claim 1, wherein the external environment includes a radio wave intensity detected through the wireless unit.

5. The communication terminal device according to claim 1, wherein the external environment includes a detection result of a base station transmitting and receiving the radio wave, the detection result being detected through the wireless unit.

6. The communication terminal device according to claim 1, further comprising:
a temperature detection unit configured to detect a temperature of the battery, wherein the external environment includes a condition of the temperature.

7. The communication terminal device according to claim 1, wherein the power supply circuit detects a voltage of the battery, and the external environment includes the voltage.

8. The communication terminal device according to claim 1, wherein the arithmetic processing unit calculates a consumption amount of the battery in accordance with a type of the operation.

9. The communication terminal device according to claim 1, wherein, when one of the types of the operations is a standby application, the arithmetic processing unit detects a movement of the communication terminal device based on a detection result of a base station as the external environment.

10. A remaining battery amount calculation method, comprising:
detecting, by an arithmetic processor, an operation performed on a communication terminal device operating based on supply of electric power from a battery;
detecting a duration time of the operation;
detecting an external environment of the communication terminal device; and
calculating a first remaining battery amount of the battery based on the operation, the duration time, and deterioration of the external environment.

11. The remaining battery amount calculation method according to claim 10, further comprising:
calculating a second remaining battery amount of the battery based on a type of the operation and the duration time; and
calculating the first remaining battery amount so that the second remaining battery amount decreases in response to the deterioration of the external environment.

12. The remaining battery amount calculation method according to claim 10, wherein the external environment includes a radio wave intensity detected through a wireless unit.

13. The remaining battery amount calculation method according to claim 10, wherein the external environment includes a detection result of a base station transmitting and receiving a radio wave, the detection result being detected through a wireless unit.

14. The remaining battery amount calculation method according to claim 10, further comprising:
detecting a temperature of the battery; and
calculating the first remaining battery amount based on the temperature.

15. The remaining battery amount calculation method according to claim 10, further comprising:
detecting a voltage of the battery; and
calculating the first remaining battery amount based on the voltage.

16. The remaining battery amount calculation method according to claim 10, further comprising:
calculating a consumption amount of the battery in accordance with a type of the operation; and
displaying the consumption amount.

17. A computer-readable recording medium storing a remaining battery amount calculation program, the remaining battery amount calculation program comprising:
detecting an operation performed on a communication terminal device operating based on supply of electric power from a battery;
detecting a duration time of the operation;
detecting an external environment of the communication terminal device; and
calculating a first remaining battery amount of the battery based on the operation, the duration time, and deterioration of the external environment.

18. The computer-readable recording medium according to claim 17, the remaining battery amount calculation program further comprising:
calculating the first remaining battery amount so that a second remaining battery amount of the battery, which is calculated in accordance with a type of the operation and the duration time, decreases in response to deterioration of the external environment.

19. The computer-readable recording medium according to claim 17, wherein the external environment includes a radio wave intensity detected through a wireless unit.

20. The computer-readable recording medium according to claim 17, wherein the external environment includes a detection result of a base station transmitting and receiving the radio wave, the detection result being detected through a wireless unit.
